(19) United States
(12) Patent Application Publication
(10) Pub. No.: US 2011/0017253 A1
(43) Pub. Date: Jan. 27, 2011

(54) Thermionic converter

(75) Inventors: Mitsuhiro Kataoka, Kasugai-city (JP); Yuji Kimura, Nagoya-city (JP); Eiichi Okuno, Mizuho-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/805,153

(22) Filed: Jul. 15, 2010

(30) Foreign Application Priority Data
Jul. 27, 2009 (JP) 2009-173989

(51) Int. Cl. H01L 35/30

(52) U.S. Cl. 136/205

(57) ABSTRACT

A thermionic converter includes an emitter electrode and a collector electrode. The emitter electrode includes a P-type diamond semiconductor layer doped with a P-type impurity. The emitter electrode is configured to emit a thermion from the P-type diamond semiconductor layer when heat is applied from an external power source. The collector electrode includes an N-type diamond semiconductor layer doped with an N-type impurity. The N-type diamond semiconductor layer opposes the P-type diamond semiconductor layer and is located at a predetermined distance from the P-type diamond semiconductor layer. The collector electrode is configured to receive the thermion emitted from the emitter electrode at the N-type diamond semiconductor layer.

### CROSS REFERENCE TO RELATED APPLICATIONS

The present application is based on and claims priority to Japanese Patent Application No. 2009-173989 filed on Jul. 27, 2009, the contents of which are incorporated in their entirety herein by reference.

### BACKGROUND OF THE INVENTION

1. Field of the Invention The present invention relates to a thermionic converter that converts thermal energy into electric energy.

2. Description of the Related Art

JP 2004-349398 A discloses a thermionic converter, that converts thermal energy into electric energy using a phenomenon that thermions are emitted from a surface of an electrode at a high temperature. In the thermionic converter, a distance between electrodes is set to be nano meters so as to improve a thermion emission efficiency using a tunnel phenomenon. In addition, a plurality of the thermionic converters is coupled in series so as to generate a high electromotive. force.

However, it is difficult to maintain such a short distance between the electrodes, and the distance is a limit of a machining accuracy. I addition, heat may be transferred from an emitter electrode to a collector electrode through a wire between the thermionic converters coupled in series, and power generation efficiency may be reduced.

According to the following non-patent document 1, when a diamond semiconductor is used for an emitter electrode and a collector electrode in a thermionic converter, thermions can be efficiently emitted from a surface of the electrode due to a negative electron affinity (NEA) and a highly-efficient power generation can be achieved.

Non-Patent Document 1: F. A. M. Koeck, Y. j. Tang, R. j. Nemanich, Organizing Committee NDNC2007, NDNC 2007 New Diamond and Nano Carbons 2007, May 28, 2007, p 97, “Direct thermionic energy conversion from nitrogen doped diamond films,” North Carolina State University, Raleigh, N.C., USA, Arizona State University, Tempe, Ariz., USA.

However, just using the diamond semiconductor for the emitter electrode and the collector electrode may cause a difficulty that an electromotive force is small. This is because a nitrogen-doped diamond semiconductor is used for both of the emitter electrode and the collector electrode, both of the electrodes become N-type semiconductor, and a difference in Fermi level between the emitter electrode and the collector electrode is small.

### SUMMARY OF THE INVENTION

In view of the foregoing problems, it is an object of the present invention to provide a thermionic converter that can generate a large electromotive force.

A thermionic converter includes an emitter electrode and a collector electrode. The emitter electrode includes a P-type diamond semiconductor layer doped with a P-type impurity. The emitter electrode is configured to emit a thermion from the P-type diamond semiconductor layer when heat is applied from an external power source. The collector electrode includes an N-type diamond semiconductor layer doped with an N-type impurity. The N-type diamond semiconductor layer opposes the P-type diamond semiconductor layer and is located at a predetermined distance from the P-type diamond semiconductor layer. The collector electrode is configured to receive the thermion emitted from the emitter electrode at the N-type diamond semiconductor layer.

In the thermionic converter, a P-type diamond semiconductor is used for the emitter electrode, and an N-type diamond semiconductor is used for the collector electrode. Thus, a difference in Fermi level between the emitter electrode and the collector electrode can be large, and the thermionic converter can generate a large electromotive force.

### BRIEF DESCRIPTION OF THE DRAWINGS

Additional objects and advantages of the present invention will be more readily apparent from the following detailed description of exemplary embodiments when taken together with the accompanying drawings. In the drawings:

FIG. 1 is a diagram illustrating a thermionic converter according to a first embodiment of the present invention;

FIG. 2 is a diagram illustrating an energy band for explaining an operating principle of the thermionic converter;

FIG. 3A is a diagram illustrating an energy band in a case where a surface of a diamond semiconductor thin layer is terminated with hydrogen; and

FIG. 3B is a diagram illustrating an energy band in a case where a surface of a diamond semiconductor thin layer is terminated with oxygen.

### DETAILED DESCRIPTION OF THE EXEMPLARY EMBODIMENTS

### First Embodiment

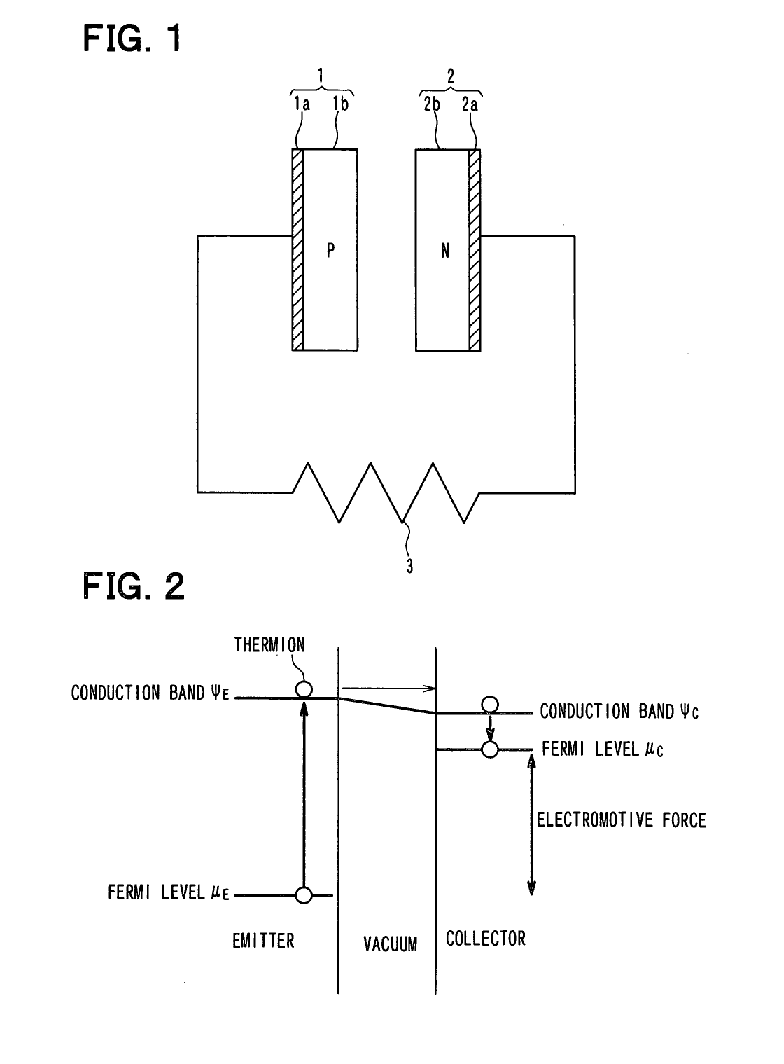

A thermionic converter according to a first embodiment of the present invention will be described with reference to FIG. 1.

The thermionic converter includes an emitter electrode 1, a collector electrode 2, and a load 3. The emitter electrode 1 and the collector electrode 2 oppose each other. The load 3 is coupled between the emitter electrode 1 and the collector electrode 2. The thermionic converter supplies electricity to the load 3 using thermions transferring between the emitter electrode 1 and the collector electrode 2.

The emitter electrode 1 includes a substrate 1a and a diamond semiconductor thin layer 1b formed on the substrate 1a. The collector electrode 2 includes a substrate 2a and a diamond semiconductor thin layer 2b formed on the substrate 2a. Each of the substrates 1a and 2a may be, for example, a diamond substrate or a molybdenum substrate. When a diamond substrate is used, the diamond substrate may be, for example, 3 mm square. When the molybdenum substrate is used, the molybdenum substrate may be, for example, 1 inch square. In a general diamond substrate, impurities are not doped. However, a diamond substrate doped with impurities such as boron may also be used.

The diamond semiconductor thin layers 1b and 2b may be formed on the substrates 1a and 2a, for example, by a chemical vapor deposition (CVD) method or a sputtering method.. The CVD method includes a micro wave CVD. The sputtering method includes a plasma sputtering method. Diamond in the diamond semiconductor thin layers 1b and 2b may be either a single crystal or a poly crystal. For example, when a diamond substrate formed by a high-pressure synthesis is used and each of the diamond semiconductor thin layers 1b and 2b is formed on the diamond substrate by the CVD method, diamond in each of the diamond semiconductor thin layers 1b and 2b becomes a signal crystal. Thicknesses of the diamond semiconductor thin layers 1b and 2b are not limited because it is not confirmed that a thermionic conversion depends on the thicknesses. However, It is preferred that the thicknesses of the diamond semiconductor thin layers, 1b and 2b are even in the whole area of surfaces of the substrates 1a and 2a.

The diamond semiconductor thin layer 1b in the emitter electrode 1 has a P-type conductivity; The diamond semiconductor thin layer 2b in the collector electrode 2 has an N-type conductivity. For example, the diamond semiconductor thin layer 1b is doped with boron as a P-type impurity and the diamond semiconductor thin layer 2b is doped with nitrogen as an N-type impurity.

The emitter electrode 1 and the collector electrode 2 are arranged in such a manner that the diamond semiconductor thin layers 1b and 2b oppose each other. A distance between the diamond semiconductor thin layers 1b and 2b is set so as to be appropriate to a thermionic conversion. For example, the distance is from 20 μm to 100 μm. The distance may be maintained by providing a clearance between the emitter electrode 1 and the collector electrode 2. The distance may also be maintained by disposing an insulating layer having a thickness corresponding to the distance between the diamond semiconductor thin layers 1b and 2b and fixing the diamond semiconductor thin layers 1b and 2b on opposite sides of the insulating layer.

Next, an operation and exemplary effects of the thermionic converter according to the present embodiment will be described with reference to an energy band diagram shown in FIG. 2. In FIG. 2, a space between the emitter electrode 1 and the collector electrode 2 is set to be vacuum for making a principle of operation easy to understand.

The thermionic converter converts thermal energy into electric energy using a phenomenon that thermions are emitted from a surface of an electrode at a high temperature. When heat is transferred from an external heat source to the emitter electrode 1, thermions are excited to a conduction band of the P-type diamond semiconductor that configurates the diamond semiconductor thin layer 1b of the emitter electrode 1.

Because the conduction band of the P-type diamond semiconductor has a negative electron affinity, the conduction band is higher than a vacuum level. The thermions excited to the conduction band are emitted to the vacuum without barrier. The collector electrode 2 is set at a low temperature, the space between the emitter electrode 1 and the collector electrode 2 is set to vacuum, and the distance between the emitter electrode 1 and the collector electrode 2 is short. Thus, the thermions can transfer from the surface of the emitter electrode 1 to the surface of the collector electrode 2. The thermions transferred to the collector electrode 2 can return to the emitter electrode 1 through the load 3. Thus, the thermionic converter can supply electricity to the load 3.

In the thermionic converter, the diamond semiconductor is used for the emitter electrode 1. Due to an effect of the negative electron affinity, thermions can be emitted from the surface of the emitter electrode 1 without barrier. Thus, the thermionic converter can emit thermions with high efficiency.

The P-type diamond semiconductor is used for the emitter electrode 1 and the N-type diamond semiconductor is used for the collector electrode 2. Thus, the difference in Fermi level between the emitter electrode 1 and the collector electrode 2 can be large, and an electromotive force can be large. When boron is doped to the diamond semiconductor thin layer 1b of the emitter electrode 1, an acceptor level is at about 5.1 eV from the conduction band. When nitrogen is doped to the diamond semiconductor thin layer 2b of the collector electrode 2, a donor level is at about 1.7 eV from the conduction band. Thus, the difference in the Fermi level becomes about 3.4 eV and the electromotive force can be large. Therefore, the thermionic converter can supply electricity to the load 3 based on the large electromotive force.

Even when both of the emitter electrode 1 and the collector electrode 2 are made of diamond semiconductor, a large electromotive force can be generated by using the P-type diamond semiconductor and the N-type diamond semiconductor. Thus, the thermionic converter according to the present embodiment can generate a large electromotive force using the diamond semiconductor.

### Second Embodiment

A thermionic converter according to a second embodiment of the present invention will be described below. In the thermionic converter according to the present embodiment, an impurity doped to the diamond semiconductor thin layer 2b is different from that of the first embodiment. Other parts of the thermionic converter according to the present embodiment are similar to those of the thermionic converter according to the first embodiment. Thus, a part different from the first embodiment is mainly described.

In the present embodiment, boron is doped to the diamond semiconductor thin layer 1b of the emitter electrode 1 similarly to the first embodiment, and phosphorous is doped to the diamond semiconductor thin layer 2b of the collector electrode 2.

When phosphorous is doped to the diamond semiconductor thin layer 2b of the collector electrode 2, an operation and effects are basically similar to those of the first embodiment, and the donor level is at about 0.6 eV from the conduction band. When boron is doped to the diamond semiconductor thin layer 1b of the emitter electrode 1, the accepter level is at about 5.1 eV from the conduction band. Thus, the difference in the Fermi level becomes about 4.5 eV. Therefore, thermionic converter according to the present embodiment can generate larger electromotive force than the thermionic converter according to the first embodiment.

### Third Embodiment

A thermionic converter according to a third embodiment of the present invention will be described below. In the thermionic converter according to the present embodiment, an impurity doped to the diamond semiconductor thin layer 2b is different from that of the first embOdiment. Other parts of the thermionic converter according to the present embodiment are similar to those of the thermionic converter according to the first embodiment. Thus, a part different from the first embodiment is mainly described.

In the present embodiment, boron is doped to the diamond semiconductor thin layer 1b of the emitter electrode 1 similarly to the first embodiment, and sulfur is doped to the diamond semiconductor thin layer 2b of the collector electrode 2.

When sulfur is doped to the diamond semiconductor thin layer 2b of the collector electrode 2, an operation and effects are basically similar to those of the first embodiment, and the donor level is at about 0.4 eV from the conduction band. When boron is doped to the diamond semiconductor thin layer 1b of the emitter electrode 1, the accepter level is at about 5.1 eV from the conduction band. Thus, the difference in the Fermi level becomes about 4.7 eV. Therefore, thermionic converter according to the present embodiment can generate larger electromotive force than the thermionic converter according to the first embodiment.

### Fourth Embodiment

A thermionic converter according to a fourth embodiment of the present invention will be described. In the thermionic converter according to the present embodiment, a configuration of the emitter electrode 1 is changed from those of the first to third embodiments. Other parts of the thermionic converter according to the present embodiment are similar to those of the thermionic converters according to the first to third embodiments. Thus, a part different from the first to third embodiments is mainly described.

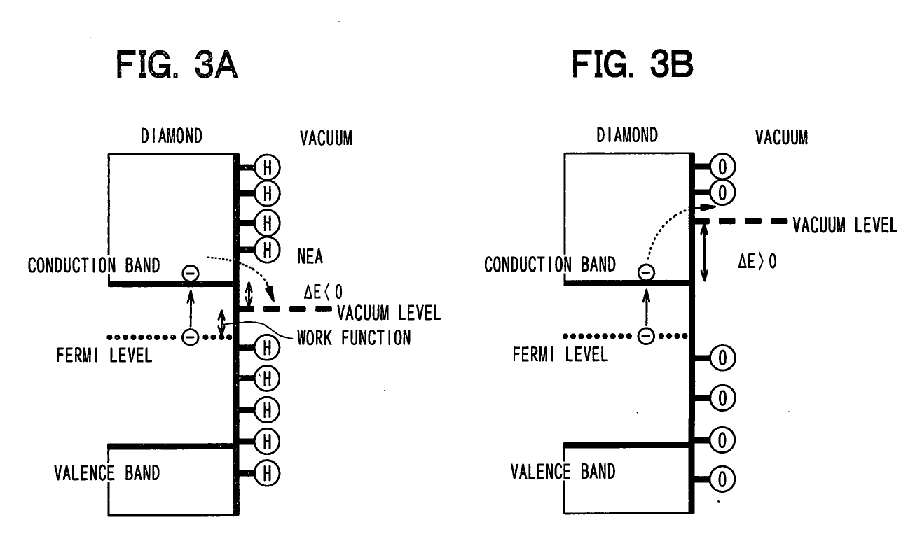

In the present embodiment, a surface of the diamond semiconductor thin layer 1b of the emitter electrode 1 is terminated with hydrogen. When the surface of the diamond semiconductor thin layer 1b is terminated with hydrogen, the negative electron affinity can be stable. Thus, the thermionic converter according to the present embodiment can emit thermions with high efficiency for a long time. A case where the surface of the diamond semiconductor thin layer 1b is terminated with hydrogen and a case where the surface of the diamond semiconductor thin layer 1b is terminated with oxygen will be compared with reference to FIG. 3A and FIG. 3B.

When the surface of the diamond semiconductor thin layer 1b is terminated with hydrogen as shown in FIG. 3A, the work function represented by a difference between the vacuum level and the Fermi level becomes small, and the vacuum level is lower than the conduction band (ΔE<0). Thus, electrons in the conduction band are emitted to vacuum when energy=0. On the other hand, when the surface of the diamond semiconductor thin layer 1b is terminated with oxygen as shown in FIG. 3B, the work function becomes large, and the vacuum level is higher than the conduction band (ΔE>0). Thus, energy is needed to emit electrons in the conduction band to vacuum..

In the above-described way, the negative electron affinity can be changed by changing a termination structure of the surface of the diamond semiconductor thin layer 1b. When the surface of the diamond semiconductor thin layer 1b is terminated with hydrogen, the negative electron affinity can be stable, and the thermionic converter can emit thermions with high efficiently for a long time.

### Other Embodiments

Although the present invention has been fully described in connection with the exemplary embodiments thereof with reference to the accompanying drawings, it is to be noted that various changes and modifications will become apparent to those skilled in the art.

For example, in the above-described embodiments, the substrates 1a and 2a are made of diamond or molybdenum, as an example. As long as the diamond semiconductor thin layers 1b and 2b can be formed on the substrates 1a and 2a, respectively, the substrates 1a and 2a may also be made of other material. The diamond semiconductor thin layers 1b and 2b may also be formed by a method other than the CVD method.

What is claimed is:

1. A thermionic converter comprising
an emitter electrode including a P-type diamond, semiconductor layer doped with a P-type impurity, the emitter electrode configured to emit a thermion from the P-type diamond semiconductor layer when heat is applied from an external power source; and
a collector electrode including an N-type diamond semiconductor layer doped with an N-type impurity, the N-type diamond semiconductor layer opposing the P-type diamond semiconductor layer and located at a predetermined distance from the P-type diamond semiconductor layer, the collector electrode configured to receive the thermion emitted from the emitter electrode at the N-type diamond semiconductor layer.

2. The thermionic converter according to claim 1, wherein
the P-type impurity includes boron and the N-type impurity includes nitrogen.

3. The thermionic converter according to claim 1, wherein
the P-type impurity includes boron and the N-type impurity includes phosphorous.

4. The thermionic converter according to claim 1, wherein
the P-type impurity includes boron and the N-type impurity includes sulfur.

5. The thermionic converter according to claim 1, wherein
a surface of the P-type diamond semiconductor layer is terminated with hydrogen.
